(19) United States
(12) Patent Application Publication
(10) Pub. No.: US 2010/0295036 A1
(43) Pub. Date: Nov. 25, 2010

(54) STRUCTURE FOR MAKING SOLUTION PROCESSED ELECTRONIC DEVICES

(75) Inventors: Yaw-Ming A. Tsai, Pak Shek Kok, N.T. (HK); Matthew Stainer, Goleta (GB)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I. DU PONT DE NEMOURS AND COMPANY, Wilmington, DE (US)

(21) Appl. No.: 12/863,701

(22) PCT Filed: Jan. 29, 2009
(86) PCT No.: PCT/US09/32319

§ 371 Date: Jul. 20, 2010

Related U.S. Application Data
(60) Provisional application No. 61/025,341, filed on Feb. 1, 2008.

(51) Int. Cl. H01L 51/10; H01L 51/40

(52) U.S. Cl. 257/40; 438/99; 257/E51.002

(57) ABSTRACT

There is provided a process for forming an organic electronic device wherein a TFT substrate having a non-planar surface has deposited over that substrate a planarization layer such that a substantially planar substrate, or planarized substrate, is formed. A multiplicity of thin first electrode structures having a first thickness and having tapered edges with a taper angle of no greater than 75° are formed over the planarized substrate. A multiplicity of active layers is formed over the planarized substrate. Then a buffer layer is formed by liquid deposition of a composition comprising a buffer material in a first liquid medium. The buffer layer has a second thickness which is at least 20% greater than the first thickness. A chemical containment pattern defining pixel openings is then formed over the buffer layer. A composition comprising a first active material in a second liquid medium is deposited into at least a portion of the pixel openings. Then a second electrode is formed.

### RELATED APPLICATION

This application claims priority under 35 U.S.C. §119(e) from U.S. Provisional Application No. 60/025,341 filed Feb. 1, 2008, which is incorporated by reference in its entirety.

### BACKGROUND INFORMATION

1. Field of the Disclosure

This disclosure relates in general to electronic devices and processes for forming the same. More specifically, it relates to backplane structures and devices formed by solution processing using the backplane structures.

2. Description of the Related Art

Electronic devices, including organic electronic devices, continue to be more extensively used in everyday life. Examples of organic electronic devices include organic light-emitting diodes (“OLEDs”). A variety of deposition techniques can be used in forming layers used in OLEDs. Liquid deposition techniques include printing techniques such as ink-jet printing and continuous nozzle printing.

As the devices become more complex and achieve greater resolution, the use of active matrix circuitry with thin film transistors (“TFTs”) becomes more necessary. However, surfaces of most TFT substrates are not planar. Liquid deposition onto these non-planar surfaces can result in non-uniform films. The non-uniformity may be mitigated by the choice of solvent for the coating formulation and/or by controlling the drying conditions. However, there still exists a need for a TFT substrate design that will result in improved film uniformity.

### SUMMARY

In one embodiment, there is provided a process for forming an organic electronic device, the process comprising:

providing a TFT substrate;

forming a planarization layer over the substrate to form a planarized substrate;

forming over the planarized substrate a multiplicity of thin first electrode structures having a first thickness, wherein the electrode structures have tapered edges with a taper angle of no greater than 75°;

forming over the planarized substrate a multiplicity of layers of active materials;

forming a buffer layer by liquid deposition of a composition comprising a buffer material in a first liquid medium, the buffer layer having a second thickness, wherein the second thickness is at least 20% greater than the first thickness;

forming over the buffer layer a chemical containment pattern defining pixel openings;

depositing into at least a portion of the pixel openings a composition comprising a first active material in a second liquid medium; and

forming a second electrode.

In some embodiments, the process also includes removing excess planarization materials.

The planarization layer may be formed of inorganic or organic planarization materials.

There is also provided an organic electronic device comprising, in order:

a TFT substrate;

a planarization layer;

a multiplicity of layers of active materials;

a multiplicity of thin first electrode structures having a first thickness, wherein the electrode structure have tapered edges with a taper angle of no greater than 75°;

a buffer layer having a second thickness, wherein the second thickness is at least 20% greater than the first thickness;

a chemical containment pattern defining pixel openings;

an active layer in at least a portion of the pixel openings; and

a second electrode.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1A includes a schematic illustration of the deposition of organic planarization film to a non-polar substrate.

FIG. 1B includes a schematic illustration of a planarized substrate after deposition of an inorganic planarization film and layers of semiconductive active materials over the planarized substrate.

FIG. 2 includes, as illustration, a schematic diagram of a backplane for an electronic device with inorganic planarization film, as described herein.

FIG. 3 includes as illustration, a schematic diagram of an electrode as described herein.

FIG. 4 includes as illustration, a schematic diagram of a backplane for an electronic device, as described herein.

FIG. 5 includes as illustration, a schematic diagram of an electrode and buffer layer, as described herein.

FIG. 6 includes a schematic diagram illustrating contact angle.

Skilled artisans will appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments are described above in this specification and are merely exemplary and not limiting. After reading this specification, skilled artisans will appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the Backplane, the Buffer Layer, the Chemical Containment Layer, the Organic Active Layer, the Second Electrode, and Other Device Layers.

### 1. Definitions and Clarification of Terms

Before addressing details of embodiments described below, some terms are defined or clarified.

As used herein, the term “active” when referring to a layer or material is refers to a layer or material that electronically facilitates the operation of the device. Examples of active materials include, but are not limited to, materials that conduct, inject, transport, or block a charge, where the charge can be either an electron or a hole. Examples also include a layer or material that has electronic or electro-radiative properties. An active layer material may emit radiation or exhibit a change in concentration of electron-hole pairs when receiving radiation.

The term “active matrix” is intended to mean an array of electronic components and corresponding driver circuits within the array.

The term “backplane” is intended to mean a workpiece on which organic layers can be deposited to form an electronic device.

The term “circuit” is intended to mean a collection of electronic components that collectively, when properly connected and supplied with the proper potential(s), performs a function. A circuit may include an active matrix pixel within an array of a display, a column or row decoder, a column or row array strobe, a sense amplifier, a signal or data driver, or the like.

The term “electrode” is intended to mean a structure configured to transport carriers. For example, an electrode may be an anode, a cathode. Electrodes may include parts of transistors, capacitors, resistors, inductors, diodes, organic electronic components and power supplies.

The term “electronic device” is intended to mean a collection of circuits, electronic components, or combinations thereof that collectively, when properly connected and supplied with the proper potential(s), performs a function. An electronic device may include, or be part of, a system. Examples of electronic devices include displays, sensor arrays, computer systems, avionics, automobiles, cellular phones, and many other consumer and industrial electronic products.

The term “insulative” is used interchangeably with “electrically insulating”. These terms and their variants are intended to refer to a material, layer, member, or structure having an electrical property such that it substantially prevents any significant current from flowing through such material, layer, member or structure.

The term “layer” is used interchangeably with the term “film” and refers to a coating covering a desired area. The area can be as large as an entire device or as small as a specific functional area such as the actual visual display, or as small as a single sub-pixel. Films can be formed by any conventional deposition technique, including vapor deposition, liquid deposition and thermal transfer. Typical liquid deposition techniques include, but are not limited to, continuous deposition techniques such as spin coating, gravure coating, curtain coating, dip coating, slot-die coating, spray coating, and continuous nozzle coating; and discontinuous deposition techniques such as ink jet printing, gravure printing, and screen printing.

The term “light-transmissive” is used interchangeably with “transparent” and is intended to mean that at least 50% of incident light of a given wavelength is transmitted. In some embodiments, 70% of the light is transmitted.

The term “liquid composition” is intended to mean a liquid medium in which a material is dissolved to form a solution, a liquid medium in which a material is dispersed to form a dispersion, or a liquid medium in which a material is suspended to form a suspension or an emulsion. “Liquid medium” is intended to mean a material that is liquid without the addition of a solvent or carrier fluid, i.e., a material at a temperature above its solidification temperature.

The term “opening” is intended to mean an area characterized by the absence of a particular structure that surrounds the area, as viewed from the perspective of a plan view.

The term “organic electronic device” is intended to mean a device including one or more semiconductor layers or materials. Organic electronic devices include: (1) devices that convert electrical energy into radiation (e.g., an light-emitting diode, light emitting diode display, or diode laser), (2) devices that detect signals through electronics processes (e.g., photodetectors (e.g., photoconductive cells, photoresistors, photoswitches, phototransistors, or phototubes), IR detectors, or biosensors), (3) devices that convert radiation into electrical energy (e.g., a photovoltaic device or solar cell), and (4) devices that include one or more electronic components that include one or more organic semiconductor layers (e.g., a transistor or diode).

The terms “over” and “overlying,” when used to refer to layers, members or structures within a device, do not necessarily mean that one layer, member or structure is immediately next to or in contact with another layer, member, or structure. Similarly, the terms “under” and “underlying” do not necessarily mean that one layer, member or structure is immediately next to or in contact with another layer, member, or structure. When a first layer is under a second layer and in direct contact with that second layer, it is referred to as “immediately under” or “immediate underlying”.

The term “perimeter” is intended to mean a boundary of a layer, member, or structure that, from a plan view, forms a closed planar shape.

The term “photoresist” is intended to mean a photosensitive material that can be formed into a layer. When exposed to activating radiation, at least one physical property and/or chemical property of the photoresist is changed such that the exposed and unexposed areas can be physically differentiated.

The term “structure” is intended to mean one or more patterned layers or members, which by itself or in combination with other patterned layer(s) or member(s), forms a unit that serves an intended purpose. Examples of structures include electrodes, well structures, cathode separators, and the like.

The term “TFT substrate” is intended to mean an array of TFTs and/or driving circuitry to make a panel function on a base support.

The term “support” or “base support” is intended to mean a base material that can be either rigid or flexible and may be include one or more layers of one or more materials, which can include, but are not limited to, glass, polymer, metal or ceramic materials or combinations thereof.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### 2. The Backplane

The backplane for the process described herein comprises a TFT substrate, a planarization layer, a multiplicity of thin first electrode structures having a tapered edge, and a multiplicity of active layers. The planarization layer may be comprised of inorganic or organic materials.

TFT substrates are well known in the electronic arts. The base support may be a conventional support as used in organic electronic device arts and may include an electrode material such as ITO. The base support can be flexible or rigid, organic or inorganic. In some embodiments, the base support is transparent. In some embodiments, the base support is glass or a flexible organic film. The TFT array may be located over or within the support, as is known. The support can have a thickness in the range of about 12 to 2500 microns. The term “first electrode structure” as used herein thus refers to a substrate including base support, electrode, and TFT structure.

The term “thin-film transistor” or “TFT” is intended to mean a field-effect transistor in which at least a channel region of the field-effect transistor is not principally a portion of a base material of a substrate. In one embodiment, the channel region of a TFT includes a-Si, polycrystalline silicon, or a combination thereof. The term “field-effect transistor” is intended to mean a transistor, whose current carrying characteristics are affected by a voltage on a gate electrode. A field-effect transistor includes a junction field-effect transistor (JFET) or a metal-insulator-semiconductor field-effect transistor (MISFET), including a metal-oxide-semiconductor field-effect transistor (MOSFETs), a metal-nitride-oxide-semiconductor (MNOS) field-effect transistor, or the like. A field-effect transistor can be n-channel (n-type carriers flowing within the channel region) or p-channel (p-type carriers flowing within the channel region). A field-effect transistor may be an enhancement-mode transistor (channel region having a different conductivity type compared to the transistor's S/D regions) or depletion-mode transistor (the transistor's channel and S/D regions have the same conductivity type).

TFT structures and designs are well known. The TFT structure usually includes gate, source, and drain electrodes, and a sequence of inorganic insulating layers, usually referred to as a buffer layer, gate insulator, and interlayer.

There is a planarization layer provided over the TFT substrate. As used herein, the term “thick”, when referring to the planarization layer, is intended to mean a thickness of at least 5000 Å in the direction perpendicular to the plane of the substrate. The planarization layer smoothes over the rough features and any particulate material of the TFT substrate, and prevents parasitic capacitance. In some embodiments, the planarization layer is 0.5 to 5 microns in thickness; in some embodiments, 1 to 3 microns.

Any inorganic dielectric material can be used as a planarization film for the planarization layer. In general, the inorganic material should have a dielectric constant of at least 2.5. In some embodiments the inorganic material is selected from SiOₓ, SiNₓ and SiₙNₓ. In some embodiments the inorganic material may be selected from silica and silicon nitride.

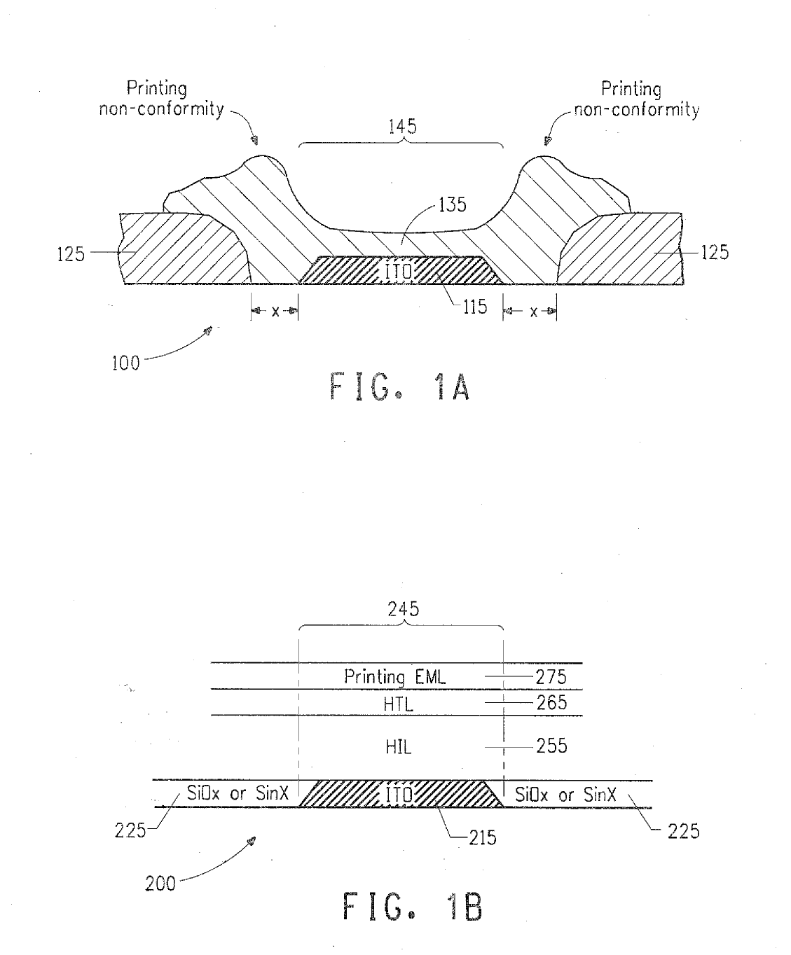

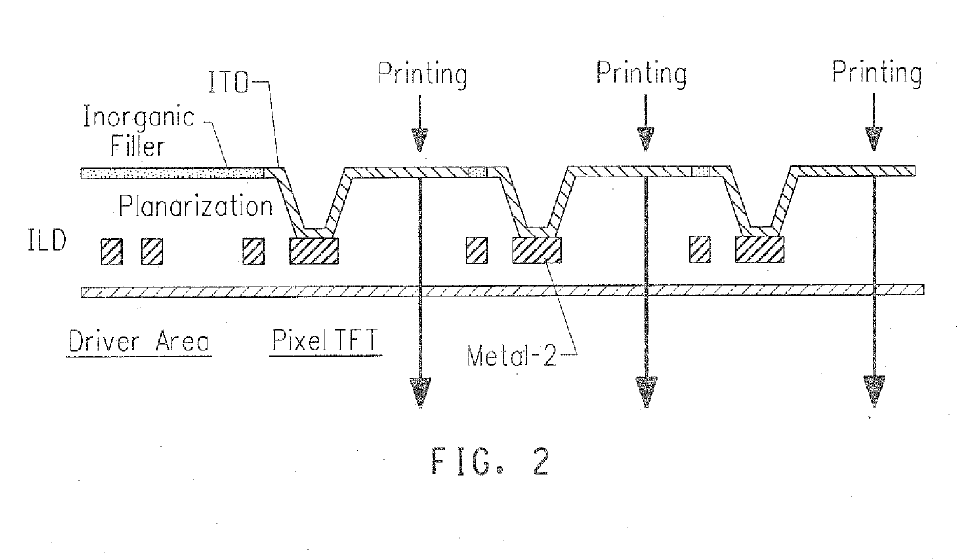

In some embodiments a thin inorganic planarization film is deposited over the substrate and the excess removed to produce a planarized substrate having an inorganic layer with substantially the same thickness as the ITO or TFT non-planarities (i.e., non-uniform structures) over the same substrate. This is illustrated in FIG. 1B. Removal of excess may be done by known techniques such as chemical mechanical polishing (CMP). In another embodiment the inorganic film may be deposited as a thin layer adjacent to non-planar structures on the same substrate and having essentially the same thickness as the non-planar structures, as a filler for planarization. Refer also to FIG. 1B. The surface of the substrate after depositing the planarization film may optionally be smoothed by any method including CMP if desired to reduce the possibility of shorting defects between the anode (e.g., ITO) and the cathode.

Any organic dielectric material can be used for the planarization layer. In general, the organic material should have a dielectric constant of at least 2.5. In some embodiments, the organic material is selected from the group consisting of epoxy resins, acrylic resins, and polyimide resins. Such resins are well known, and many are commercially available.

In some embodiments the organic planarization layer is deposited with a half-tone mask over the substrate so that the organic planarization film over the ITO may readily be removed, leaving the planarization layer at substantially the same thickness as the non-planar structures on the substrate. In some embodiments, the planarization layer is patterned to remove it from the areas where the electronic device will be sealed. Patterning can be accomplished using standard photolithographic techniques. In some embodiments, the planarization layer is made from a photosensitive material known as a photoresist. In this case, the layer can be imaged and developed to form the patterned planarization layer. The photoresist can be positive-working, which means that the photoresist layer becomes more removable in the areas exposed to activating radiation, or negative-working, which means this it is more easily removed in the non-exposed areas. In some embodiments, the planarization layer itself is not photosensitive. In this case, a photoresist layer can be applied over the planarization layer, imaged, and developed to form the patterned planarization layer. In some embodiments, the photoresist is then stripped off. Techniques for imaging, developing, and stripping are well known in the photoresist art area. In other embodiments any excess of the organic planarization film may be removed by known smoothing techniques as described above in relation to the inorganic planarization films. Smoothing may also optionally be performed to reduce the possibility of shorting defects.

A multiplicity of active layers is then formed on the planarized substrate. Active layers include layers such as hole injection, hole transport, electron injection, electron transport, emissive, and buffer layers. A layer may include more than one type of material. For example, an emissive layer may include both luminescent “dopant” materials and “host” materials.

FIG. 1A depicts a substrate 100 comprising an ITO electrode 115 which is shown to be non-planar over the entire surface of the substrate. An organic planarization material 125 is deposited in excess on either side of the electrode layer 115. In the embodiment shown in FIG. 1A, excess planarization material 125 has not been removed, yet the print layer 135 may be deposited in a uniform planar layer over the substrate within the effective emissive area 145. The letter x represents area over the surface of the substrate outside the effective emissive area 145. Additional active layers, not shown, may be applied in similar planar uniformity within the effective emissive area.

FIG. 1B depicts a substrate 200 comprising ITO electrode 215 and inorganic planarization material 225 applied in solution as a planarization filler at substantially the same thickness as the ITO electrode 215. Active layers including a hole injection layer 255, hole transport layer 265, and emissive layer 275 are applied with planar uniformity both within the effective emissive area 245 and also substantially uniformly over the entire surface area of the planarized substrate 200. Additional layers, not shown, may be similarly applied.

The embodiment is shown in close detail in FIG. 2, where the substrate depicted includes TFT structures.

A multiplicity of thin first electrode structures is then formed on the planarization layer. As used herein, the term “thin”, when referring to the first electrode structures, is intended to mean a thickness no greater than 1500 Å in the direction perpendicular to the plane of the substrate. In some embodiments, the thickness is no greater than 1200 Å; in some embodiments, no greater than 800 Å. The electrodes may be anodes or cathodes. In some embodiments, the electrodes are formed as parallel strips. Alternately, the electrodes may be a patterned array of structures having plan view shapes, such as squares, rectangles, circles, triangles, ovals, and the like. Generally, the electrodes may be formed using conventional processes (e.g. deposition, patterning, or a combination thereof).

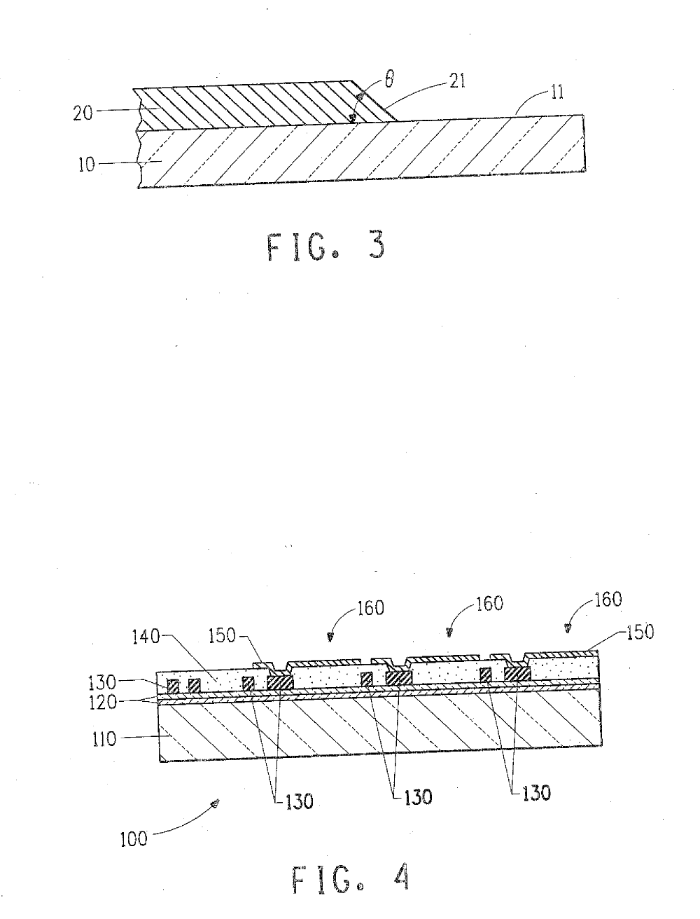

The electrodes have a tapered edge with a taper angle of no greater than 75°. As used herein, the term “taper angle” as it refers to the electrode structure, is intended to mean the internal angle formed by the electrode edge and the underlying planarization layer. This is shown schematically in FIG. 3. Planarization layer 10 has an upper surface 11. Electrode structure 20, on the planarization layer, has a tapered edge 21. Tapered edge 21 forms an internal angle Θ with the planarization layer surface. Angle Θ is the taper angle. For a conventional, non-tapered electrode, the internal angle Θ will be 90°. The electrodes described herein have a taper angle of no greater than 75°; in some embodiments, no greater than 40°.

In some embodiments, the first electrode structures are tapered on at least the sides of the electrode that are parallel to the printing direction for the deposition of the organic active layer. In some embodiments, the first electrode structures are tapered on all sides.

In some embodiments, the electrodes are transparent. In some embodiments, the electrodes comprise a transparent conductive material such as indium-tin-oxide (ITO). Other transparent conductive materials include, for example, indium-zinc-oxide (IZO), zinc oxide, tin oxide, zinc-tin-oxide (ZTO), elemental metals, metal alloys, and combinations thereof. In some embodiments, the electrodes are anodes for the electronic device. The electrodes can be formed using conventional techniques, such as selective deposition using a stencil mask, or blanket deposition and a conventional lithographic technique to remove portions to form the pattern.

The taper geometry can be formed using any conventional techniques. In some embodiments, the taper is formed by dry or wet etching techniques. Such techniques are well known.

One exemplary backplane 100 is shown schematically in FIG. 4. The TFT substrate includes: glass substrate 110, inorganic insulative layers 120, and various conductive lines 130 for gate electrodes or gate lines and source/drain electrodes or data lines. There is an organic planarization layer 140. A pixellated electrode is shown as 150, with pixel areas 160.

### 3. The Buffer Layer

The term “organic buffer layer” or “organic buffer material” is intended to mean electrically conductive or semiconductive organic materials and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. Organic buffer materials may be polymers, oligomers, or small molecules, and may be in the form of solutions, dispersions, suspensions, emulsions, colloidal mixtures, or other compositions.

The organic buffer layer can be formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like. The organic buffer layer can comprise charge transfer compounds, and the like, such as copper phthalocyanine and the tetrathiafulvalene-tetracyanoquinodimethane system (TTF-TCNQ). In one embodiment, the organic buffer layer is made from a dispersion of a conducting polymer and a colloid-forming polymeric acid. Such materials have been described in, for example, published U.S. patent applications 2004-0102577, 2004-0127637, and 2005/205860.

The organic buffer layer has a thickness that is at least 20% greater than the thickness of the first electrode structures. In some embodiments, the thickness is at least 50% greater.

The buffer layer is formed by liquid deposition of a composition comprising the buffer material and a first liquid medium. Any liquid deposition technique can be used, as described above. The choice of liquid medium will depend on the specific buffer material used. In some embodiments, the first liquid medium is aqueous. In some embodiments, the first liquid medium is at least 70% by volume water.

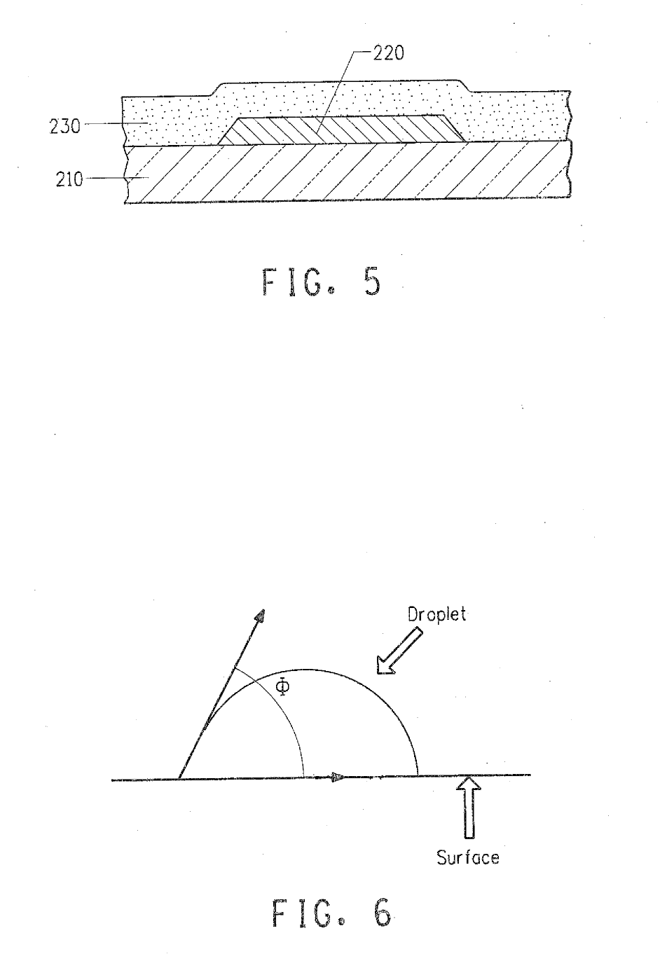

The structure formed by the application of the buffer layer is shown schematically in FIG. 5. Planarization layer 210 has electrodes structures 220 on the surface thereof. Overlying the electrode structures is buffer layer 230. Because of the tapered edge of the electrode structures and the thickness of the buffer layer, the surface is substantially planar for subsequent liquid deposition steps.

### 4. Chemical Containment Pattern

The chemical containment pattern is formed over the buffer layer. The term “chemical containment pattern” is intended to mean a pattern that contains or restrains the spread of a liquid material by surface energy effects rather than physical barrier structures. The term “contained” when referring to a layer, is intended to mean that the layer does not spread significantly beyond the area where it is deposited. The term “surface energy” is the energy required to create a unit area of a surface from a material. A characteristic of surface energy is that liquid materials with a given surface energy will not wet surfaces with a lower surface energy.

In some embodiments, the chemical containment pattern has lower surface energy than the surrounding areas. One way to determine the relative surface energies, is to compare the contact angle of a given liquid on the first organic active layer before and after treatment with the RSA. As used herein, the term “contact angle” is intended to mean the angle φ shown in FIG. 6. For a droplet of liquid medium, angle φ is defined by the intersection of the plane of the surface and a line from the outer edge of the droplet to the surface. Furthermore, angle φ is measured after the droplet has reached an equilibrium position on the surface after being applied, i.e. “static contact angle”. A variety of manufacturers make equipment capable of measuring contact angles.

The chemical containment pattern can be a separate patterned layer, or it can be a surface treatment in a pattern.

When the chemical containment pattern is present as a separate layer, it is an ultra-thin layer. In some embodiments, the layer has a thickness no greater than 500 Å; in some embodiments, no greater than 100 Å; in some embodiments, no greater than 50 Å. In some embodiments, the pattern is a monolayer.

In some embodiments, the chemical containment pattern is a layer of low surface energy material which is deposited in a pattern. Materials such as silicon fluorides or silicon nitrides can be applied in a pattern by vapor deposition. Materials such as fluorocarbons or silicones can be applied in a pattern using standard photolithographic techniques.

In some embodiments, the chemical containment pattern is formed by treatment of the immediate underlying layer with a reactive surface-active composition. The term(s) “radiating/radiation” means adding energy in any form, including heat in any form, the entire electromagnetic spectrum, or subatomic particles, regardless of whether such radiation is in the form of rays, waves, or particles. The term “radiation-sensitive” when referring to a material, is intended to mean that exposure to radiation results in a change of at least one chemical, physical, or electrical property of the material.

In some embodiments, the underlying layer which is treated to form the chemical containment pattern is the buffer layer. In some embodiments, one or more additional organic layers are present over the buffer layer. When additional layers are present, the layer coming before the active layer to be contained is the layer treated. The reactive surface-active composition (“RSA”) is a radiation-sensitive composition. When exposed to radiation, at least one physical property and/or chemical property of the RSA is changed such that the exposed and unexposed areas can be physically differentiated and a pattern can be formed. Treatment with the RSA lowers the surface energy of the material being treated.

In one embodiment, the RSA is a radiation-hardenable composition. In this case, when exposed to radiation, the RSA can become more soluble or dispersable in a liquid medium, less tacky, less soft, less flowable, less liftable, or less absorbable. Other physical properties may also be affected.

In one embodiment, the RSA is a radiation-softenable composition. In this case, when exposed to radiation, the RSA can become less soluble or dispersable in a liquid medium, more tacky, more soft, more flowable, more liftable, or more absorbable. Other physical properties may also be affected.

The radiation can be any type of radiation which results in a physical change in the RSA. In one embodiment, the radiation is selected from infrared radiation, visible radiation, ultraviolet radiation, and combinations thereof.

Physical differentiation between areas of the RSA exposed to radiation and areas not exposed to radiation, hereinafter referred to as “development,” can be accomplished by any known technique. Such techniques have been used extensively in the photoresist art. Examples of development techniques include, but are not limited to, application of heat (evaporation), treatment with a liquid medium (washing), treatment with an absorbant material (blotting), treatment with a tacky material, and the like.

In one embodiment, the RSA consists essentially of one or more radiation-sensitive materials. In one embodiment, the RSA consists essentially of a material which, when exposed to radiation, hardens, or becomes less soluble, swellable, or dispersible in a liquid medium, or becomes less tacky or absorbable. In one embodiment, the RSA consists essentially of a material having radiation polymerizable groups. Examples of such groups include, but are not limited to olefins, acrylates, methacrylates and vinyl ethers. In one embodiment, the RSA material has two or more polymerizable groups which can result in crosslinking. In one embodiment, the RSA consists essentially of a material which, when exposed to radiation, softens, or becomes more soluble, swellable, or dispersible in a liquid medium, or becomes more tacky or absorbable. In one embodiment, the RSA consists essentially of at least one polymer which undergoes backbone degradation when exposed to deep UV radiation, having a wavelength in the range of 200-300 nm. Examples of polymers undergoing such degradation include, but are not limited to, polyacrylates, polymethacrylates, polyketones, polysulfones, copolymers thereof, and mixtures thereof.

In one embodiment, the RSA consists essentially of at least one reactive material and at least one radiation-sensitive material. The radiation-sensitive material, when exposed to radiation, generates an active species that initiates the reaction of the reactive material. Examples of radiation-sensitive materials include, but are not limited to, those that generate free radicals, acids, or combinations thereof. In one embodiment, the reactive material is polymerizable or crosslinkable. The material polymerization or crosslinking reaction is initiated or catalyzed by the active species. The radiation-sensitive material is generally present in amounts from 0.001% to 10.0% based on the total weight of the RSA.

In one embodiment, the RSA consists essentially of a material which, when exposed to radiation, hardens, or becomes less soluble, swellable, or dispersible in a liquid medium, or becomes less tacky or absorbable. In one embodiment, the reactive material is an ethylenically unsaturated compound and the radiation-sensitive material generates free radicals. Ethylenically unsaturated compounds include, but are not limited to, acrylates, methacrylates, vinyl compounds, and combinations thereof. Any of the known classes of radiation-sensitive materials that generate free radicals can be used. Examples of radiation-sensitive materials which generate free radicals include, but are not limited to, quinones, benzophenones, benzoin ethers, aryl ketones, peroxides, biimidazoles, benzyl dimethyl ketal, hydroxyl alkyl phenyl acetophone, dialkoxy actophenone, trimethylbenzoyl phosphine oxide derivatives, aminoketones, benzoyl cyclohexanol, methyl thio phenyl morpholino ketones, morpholino phenyl amino ketones, alpha halogennoacetophenones, oxysulfonyl ketones, sulfonyl ketones, oxysulfonyl ketones, sulfonyl ketones, benzoyl oxime esters, thioxanthrones, camphorquinones, ketocoumarins, and Michler's ketone. Alternatively, the radiation sensitive material may be a mixture of compounds, one of which provides the free radicals when caused to do so by a sensitizer activated by radiation. In one embodiment, the radiation sensitive material is sensitive to visible or ultraviolet radiation.

In one embodiment, the RSA is a compound having one or more crosslinkable groups. Crosslinkable groups can have moieties containing a double bond, a triple bond, a precursor capable of in situ formation of a double bond, or a heterocyclic addition polymerizable group. Some examples of crosslinkable groups include benzocyclobutane, azide, oxiran, di(hydrocarbyl)amino, cyanate ester, hydroxyl, glycidyl ether, C1-10 alkylacrylate, C1-10 alkylmethacrylate, alkenyl, alkenyloxy, alkynyl, maleimide, nadimide, tri(C1-4)alkylsiloxy, tri(C1-4)alkylsilyl, and halogenated derivatives thereof. In one embodiment, the crosslinkable group is selected from the group consisting of vinylbenzyl, p-ethenylphenyl, perfluoroethenyl, perfluoroehtenyloxy, benzo-3,4-cyclobutan-1-yl, and p-(benzo-3,4-cyclobutan-1-yl)phenyl.

In one embodiment, the reactive material can undergo polymerization initiated by acid, and the radiation-sensitive material generates acid. Examples of such reactive materials include, but are not limited to, epoxies. Examples of radiation-sensitive materials which generate acid, include, but are not limited to, sulfonium and iodonium salts, such as diphenyliodonium hexafluorophosphate.

In one embodiment, the RSA consists essentially of a material which, when exposed to radiation, softens, or becomes more soluble, swellable, or dispersible in a liquid medium, or becomes more tacky or absorbable. In one embodiment, the reactive material is a phenolic resin and the radiation-sensitive material is a diazonaphthoquinone.

Other radiation-sensitive systems that are known in the art can be used as well.

In one embodiment, the RSA comprises a fluorinated material. In one embodiment, the RSA comprises an unsaturated material having one or more fluoroalkyl groups. In one embodiment, the fluoroalkyl groups have from 2-20 carbon atoms. In one embodiment, the RSA is a fluorinated acrylate, a fluorinated ester, or a fluorinated olefin monomer. Examples of commercially available materials which can be used as RSA materials, include, but are not limited to, Zonyl® 8857A, a fluorinated unsaturated ester monomer available from E. I. du Pont de Nemours and Company (Wilmington, Del.), and 3,3,4,4,5,5,6,6,7,7,8,8,9,9,10,10,11,11,12,12,12-eneicosafluorododecyl acrylate (H₂C═CHCO₂CH₂CH₂(CF₂)₉CF₃) available from Sigma-Aldrich Co. (St. Louis, Mo.).

In one embodiment, the RSA is a fluorinated macromonomer. As used herein, the term “macromonomer” refers to an oligomeric material having one or more reactive groups which are terminal or pendant from the chain. In some embodiments, the macromonomer has a molecular weight greater than 1000; in some embodiments, greater than 2000; in some embodiments, greater than 5000. In some embodiments, the backbone of the macromonomer includes ether segments and perfluoroether segments. In some embodiments, the backbone of the macromonomer includes alkyl segments and perfluoroalkyl segments. In some embodiments, the backbone of the macromonomer includes partially fluorinated alkyl or partially fluorinated ether segments. In some embodiments, the macromonomer has one or two terminal polymerizable or crosslinkable groups.

In one embodiment, the RSA is an oligomeric or polymeric material having cleavable side chains, where the material with the side chains forms films with a different surface energy that the material without the side chains. In one embodiment, the RSA has a non-fluorinated backbone and partially fluorinated or fully fluorinated side chains. The RSA with the side chains will form films with a lower surface energy than films made from the RSA without the side chains. Thus, the RSA can be can be applied to an immediate underlying layer, exposed to radiation in a pattern to cleave the side chains, and developed to remove the side chains. This results in a pattern of higher surface energy in the areas exposed to radiation where the side chains have been removed, and lower surface energy in the unexposed areas where the side chains remain. In some embodiments, the side chains are thermally fugitive and are cleaved by heating, as with an infrared laser. In this case, development may be coincidental with exposure in infrared radiation. Alternatively, development may be accomplished by the application of a vacuum or treatment with solvent. In some embodiment, the side chains are cleavable by exposure to UV radiation. As with the infrared system above, development may be coincidental with exposure to radiation, or accomplished by the application of a vacuum or treatment with solvent.

In one embodiment, the RSA comprises a material having a reactive group and second-type functional group. The second-type functional groups can be present to modify the physical processing properties or the photophysical properties of the RSA. Examples of groups which modify the processing properties include plasticizing groups, such as alkylene oxide groups. Examples of groups which modify the photophysical properties include charge transport groups, such as carbazole, triarylamino, or oxadiazole groups.

In one embodiment, the RSA reacts with the immediate underlying area when exposed to radiation. The exact mechanism of this reaction will depend on the materials used. After exposure to radiation, the RSA is removed in the unexposed areas by a suitable development treatment. In some embodiments, the RSA is removed only in the unexposed areas. In some embodiments, the RSA is partially removed in the exposed areas as well, leaving a thinner layer in those areas. In some embodiments, the RSA that remains in the exposed areas is no greater than 50 Å in thickness. In some embodiments, the RSA that remains in the exposed areas is essentially a monolayer in thickness.

The RSA treatment can be coincidental with or subsequent to the formation of the immediate underlying layer.

In one embodiment, the RSA treatment is coincidental with the formation of the immediate underlying layer. In one embodiment, the RSA is added to the liquid composition used to form the immediate underlying layer. When the deposited composition is dried to form a film, the RSA migrates to the air interface, i.e., the top surface, of the immediate underlying layer in order to reduce the surface energy of the system.

In one embodiment, the RSA treatment is subsequent to the formation of the immediate underlying layer. In one embodiment, the RSA is applied as a separate layer overlying, and in direct contact with, the immediate underlying layer.

In one embodiment, the RSA is applied without adding it to a solvent. In one embodiment, the RSA is applied by vapor deposition. In one embodiment, the RSA is a liquid at room temperature and is applied by liquid deposition over the immediate underlying layer. The liquid RSA may be film-forming or it may be absorbed or adsorbed onto the surface of the immediate underlying layer. In one embodiment, the liquid RSA is cooled to a temperature below its melting point in order to form a second layer over the immediate underlying layer. In one embodiment, the RSA is not a liquid at room temperature and is heated to a temperature above its melting point, deposited on the immediate underlying layer, and cooled to room temperature to form a second layer over the immediate underlying layer. For the liquid deposition, any of the methods described above may be used.

In one embodiment, the RSA is deposited from a second liquid composition. The liquid deposition method can be continuous or discontinuous, as described above. In one embodiment, the RSA liquid composition is deposited using a continuous liquid deposition method. The choice of liquid medium for depositing the RSA will depend on the exact nature of the RSA material itself. In one embodiment, the RSA is a fluorinated material and the liquid medium is a fluorinated liquid. Examples of fluorinated liquids include, but are not limited to, perfluorooctane, trifluorotoluene, and hexafluoroxylene.

In some embodiments, the RSA treatment comprises a first step of forming a sacrificial layer over the underlying layer, and a second step of applying an RSA layer over the sacrificial layer. The sacrificial layer is one which is more easily removed than the RSA layer by whatever development treatment is selected. Thus, after exposure to radiation, as discussed below, the RSA layer and the sacrificial layer are removed in either the exposed or unexposed areas in the development step. The sacrificial layer is intended to facilitate complete removal of the RSA layer is the selected areas and to protect the underlying immediate underlying layer from any adverse affects from the reactive species in the RSA layer.

After the RSA treatment, the treated layer is exposed to radiation. The type of radiation used will depend upon the sensitivity of the RSA as discussed above. The exposure is patternwise. As used herein, the term “patternwise” indicates that only selected portions of a material or layer are exposed. Patternwise exposure can be achieved using any known imaging technique. In one embodiment, the pattern is achieved by exposing through a mask. In one embodiment, the pattern is achieved by exposing only select portions with a laser. The time of exposure can range from seconds to minutes, depending upon the specific chemistry of the RSA used. When lasers are used, much shorter exposure times are used for each individual area, depending upon the power of the laser. The exposure step can be carried out in air or in an inert atmosphere, depending upon the sensitivity of the materials.

In one embodiment, the radiation is selected from the group consisting of ultra-violet radiation (10-390 nm), visible radiation (390-770 nm), infrared radiation (770-10⁶ nm), and combinations thereof, including simultaneous and serial treatments. In one embodiment, the radiation is deep UV radiation, having a wavelength in the range of 200-300 nm. In another embodiment, the ultraviolet radiation is of somewhat longer wavelength, in the range 300-400 nm. In one embodiment, the radiation is thermal radiation. In one embodiment, the exposure to radiation is carried out by heating. The temperature and duration for the heating step is such that at least one physical property of the RSA is changed, without damaging any underlying layers of the light-emitting areas. In one embodiment, the heating temperature is less than 250° C. In one embodiment, the heating temperature is less than 150° C.

In one embodiment, the radiation is ultraviolet or visible radiation. In one embodiment, the radiation is applied patternwise, resulting in exposed regions of RSA and unexposed regions of RSA.

In one embodiment, patternwise exposure to radiation is followed by treatment to remove either the exposed or unexposed regions of the RSA. Patternwise exposure to radiation and treatment to remove exposed or unexposed regions is well known in the art of photoresists.

In one embodiment, the exposure of the RSA to radiation results in a change in the solubility or dispersibility of the RSA in solvents. When the exposure is carried out patternwise, this can be followed by a wet development treatment. The treatment usually involves washing with a solvent which dissolves, disperses or lifts off one type of area. In one embodiment, the patternwise exposure to radiation results in insolubilization of the exposed areas of the RSA, and treatment with solvent results in removal of the unexposed areas of the RSA.

In one embodiment, the exposure of the RSA to visible or UV radiation results in a reaction which decreases the volatility of the RSA in exposed areas. When the exposure is carried out patternwise, this can be followed by a thermal development treatment. The treatment involves heating to a temperature above the volatilization or sublimation temperature of the unexposed material and below the temperature at which the material is thermally reactive. For example, for a polymerizable monomer, the material would be heated at a temperature above the sublimation temperature and below the thermal polymerization temperature. It will be understood that RSA materials which have a temperature of thermal reactivity that is close to or below the volatilization temperature, may not be able to be developed in this manner.

In one embodiment, the exposure of the RSA to radiation results in a change in the temperature at which the material melts, softens or flows. When the exposure is carried out patternwise, this can be followed by a dry development treatment. A dry development treatment can include contacting an outermost surface of the element with an absorbent surface to absorb or wick away the softer portions. This dry development can be carried out at an elevated temperature, so long as it does not further affect the properties of the originally unexposed areas.

After treatment with the RSA, exposure to radiation, and development, there is a pattern on the immediate underlying layer having areas of low surface energy and areas of higher surface energy. In the case where part of the RSA is removed after exposure to radiation, the areas of the immediate underlying layer that are covered by the RSA will have a lower surface energy that the areas that are not covered by the RSA. The chemical containment pattern defines pixel openings.

### 5. The Organic Active Layer

An organic active layer is formed in at least a portion of the pixel areas defined by the chemical containment pattern. The organic active layer comprises active material. In some embodiments, the active material comprises photoactive material. “Photoactive” refers to a material that emits light when activated by an applied voltage (such as in a light emitting diode or chemical cell) or responds to radiant energy and generates a signal with or without an applied bias voltage (such as in a photodetector). Any organic electroluminescent (“EL”) material can be used in the photoactive layer, and such materials are well known in the art. The materials include, but are not limited to, small molecule organic fluorescent compounds, fluorescent and phosphorescent metal complexes, conjugated polymers, and mixtures thereof. The photoactive material can be present alone, or in admixture with one or more host materials. Examples of fluorescent compounds include, but are not limited to, naphthalene, anthracene, chrysene, pyrene, tetracene, xanthene, perylene, coumarin, rhodamine, quinacridone, rubrene, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Examples of conjugated polymers include, but are not limited to poly(phenylenevinylenes), polyfluorenes, poly(spirobifluorenes), polythiophenes, poly(p-phenylenes), copolymers thereof, and mixtures thereof. The photoactive layer typically has a thickness in a range of approximately 50-500 nm.

The organic active layer is deposited from a liquid composition comprising the organic active material in a second liquid medium. The choice of the liquid medium will depend on the specific organic active material used. In some embodiments, the liquid medium is one or more organic solvents.

The photoactive layer can be applied by any solution deposition technique, as described above. In one embodiment, the photoactive layer is applied by a technique selected from ink jet printing and continuous nozzle printing.

In some embodiments, a first organic active material is deposited in a first portion of pixel areas, and a second organic active material is deposited in a second portion of pixel areas. Additionally, in some embodiments, a third organic active material is deposited in a third portion of pixel areas. In some embodiments, the first organic active material comprises a first photoactive material having a first color; the second organic active material comprises a second photoactive material having a second color; and the third organic active material comprises a third photoactive material having a third color. As used herein, the color of the photoactive material refers to the wavelength at which the material emits or absorbs light. In some embodiments, the colors are red, blue and green.

### 6. The Second Electrode

The second electrode is formed over the active layer. In some embodiments, the second electrode is a cathode. The cathode can be selected from Group 1 metals (e.g., Li, Cs), the Group 2 (alkaline earth) metals, the rare earth metals including the lanthanides and the actinides. The cathode a thickness in a range of approximately 300-1000 nm.

### 7. Other Device Layers

Other layers may also be present in the device, such as the active layers described above. For example, there may be one or more hole injection and/or hole transport layers between the buffer layer and the organic active layer. There may be one or more electron transport layers and/or electron injection layers between the organic active layer and the cathode.

The term “hole transport,” when referring to a layer, material, member, or structure is intended to mean such layer, material, member, or structure facilitates migration of positive charge through the thickness of such layer, material, member, or structure with relative efficiency and small loss of charge. Although light-emitting materials may also have some charge transport properties, the term “charge transport layer, material, member, or structure” is not intended to include a layer, material, member, or structure whose primary function is light emission.

Examples of hole transport materials for layer 120 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 1,1-bis[(di-4-tolylamino) phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl] pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate. The hole transport layer typically has a thickness in a range of approximately 40-100 nm.

The term “electron transport”, when referring to a layer, material, member or structure, means such a layer, material, member or structure that promotes or facilitates migration of negative charges through such a layer, material, member or structure into another layer, material, member or structure. Examples of electron transport materials which can be used in the optional electron transport layer 140, include metal chelated oxinoid compounds, such as tris(8-hydroxyquinolato)aluminum (AlQ), bis(2-methyl-8-quinolinolato)(p-phenylphenolato) aluminum (BAlq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); and mixtures thereof. The electron-transport layer typically has a thickness in a range of approximately 30-500 nm.

As used herein, the term “electron injection” when referring to a layer, material, member, or structure, is intended to mean such layer, material, member, or structure facilitates injection and migration of negative charges through the thickness of such layer, material, member, or structure with relative efficiency and small loss of charge. The optional electron-transport layer may be inorganic and comprise BaO, LiF, or Li₂O. The electron injection layer typically has a thickness in a range of approximately 20-100 Å.

An encapsulating layer can be formed over the array and the peripheral and remote circuitry to form a substantially complete electrical device.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes slight variations above and below the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this invention to match a minimum value from one range with a maximum value from another range and vice versa.

What is claimed is:

1. A process for forming an organic electronic device, the process comprising:
providing a TFT substrate;
forming a planarization layer over the substrate to form a planarized substrate;
forming over the planarized substrate a multiplicity of thin first electrode structures having a first thickness, wherein the electrode structures have tapered edges with a taper angle of no greater than 75°;
forming over the planarized substrate a multiplicity of layers of active materials;
forming a buffer layer by liquid deposition of a composition comprising a buffer material in a first liquid medium, the buffer layer having a second thickness, wherein the second thickness is at least 20% greater than the first thickness;
forming over the buffer layer a chemical containment pattern defining pixel openings;
depositing into at least a portion of the pixel openings a composition comprising a first active material in a second liquid medium; and
forming a second electrode.

2. The process of claim 1, wherein the planarization layer comprises a planarization film comprising materials selected from inorganic and organic planarization materials.

3. The process of claim 2, wherein the planarization material is an inorganic material.

4. The process of claim 3, wherein the inorganic material is selected from materials having a general formula selected from SiOₓ, SiNₓ and SiₙNₓ.

5. The process of claim 4, wherein the inorganic material is selected from silica and silicon nitride.

6. The process of claim 2, wherein the planarization material is an organic material.

7. The process of claim 6, wherein the organic material is selected from epoxy resins, acrylic resins, and polyimide resins.

8. The process of claim 1, wherein the taper angle is no greater than 40°.

9. The process of claim 1, wherein the second thickness is at least 50% greater than the first thickness.

10. The process of claim 1, wherein the first thickness is no greater than 1500 Å.

11. The process of claim 10, wherein the first thickness is no greater than 1200 Å.

12. The process of claim 11, wherein the first thickness is no greater than 800 Å.

13. The process of claim 1, wherein the first organic active material is deposited by a technique selected from the group consisting of ink jet printing and continuous nozzle printing.

14. An organic electronic device comprising, in order:
a TFT substrate;
a planarization layer;
a multiplicity of thin first electrode structures having a first thickness, wherein the electrode structure have tapered edges with a taper angle of no greater than 75°;
a buffer layer having a second thickness, wherein the second thickness is at least 20% greater than the first thickness;
a chemical containment pattern defining pixel openings;
an active layer in at least a portion of the pixel openings; and
a second electrode.

15. The device of claim 14, wherein the planarization layer comprises a planarization film comprising material selected from inorganic and organic materials.

16. The device of claim 15, wherein the planarization material is an inorganic material.

17. The device of claim 16, wherein the material has a general formula selected from SiOₓ, SiNₓ and SiₙNₓ.

18. The device of claim 17, wherein the material is selected from silica and silicon nitride.

19. The device of claim 15, wherein the planarization material is an organic material.

20. The device of claim 19, wherein the organic material is selected from epoxy resins, acrylic resins, and polyimide resins.

21. The organic electronic device of claim 13, wherein the active layer comprises an electroluminescent material.
